(19) United States
(12) Patent Application Publication
(10) Pub. No.: US 2014/0252547 A1
(43) Pub. Date: Sep. 11, 2014

(54) SEMICONDUCTOR DEVICE HAVING INTEGRATED PASSIVE DEVICE AND PROCESS FOR MANUFACTURING THE SAME

(71) Applicant: ADVANCED SEMICONDUCTOR ENGINEERING, Inc., (US)

(72) Inventors: Chien-Hua Chen, Pingtung County (TW); Meng-Jen Wang, Pingtung County (TW); Teck-Chong Lee, Kaohsiung City (TW); Pao-Nan Lee, Kaohsiung City (TW)

(73) Assignee: ADVANCED SEMICONDUCTOR ENGINEERING, INC., Kaohsiung (TW)

(21) Appl. No.: 13/790,638

(22) Filed: Mar. 8, 2013

(51) Int. Cl. H01L 49/02

(52) U.S. Cl. CPC H01L 28/40
USPC 257/532; 438/393

(57) ABSTRACT

The present invention relates to a semiconductor device and a process for fabricating the same. In one embodiment, the semiconductor device includes a substrate and a plurality of integrated passive devices. The integrated passive devices are disposed on the substrate and include at least two capacitors which have different capacitance values.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND OF THE INVENTION

1. Field of the Invention

The present invention relates generally to the field of semiconductor devices and related manufacturing processes and, more particularly, to a semiconductor device having an integrated passive device (IPD) and process for manufacturing the same.

2. Description of the Related Art

Many conventional circuits include a passive device, such as capacitor, resistor or inductor. In order to achieve the objective of microminiaturization, there is an ongoing trend to integrate the formation of the capacitor, the resistor and the inductor into a process for fabricating a semiconductor device to obtain a semiconductor device having an integrated passive device. However, in accordance with currently known semiconductor device fabrication processes, the same kind of integrated passive devices are formed at the same time, thus resulting in the electrical properties of the integrated passive devices being the same. Therefore, it is problematic if a circuit layout needs at least two different electrical properties for the same kind of integrated passive device. For example, a RF transceiver chip needs different capacitors with different capacitance values. Therefore, there is a need in the art to provide a semiconductor device having integrated passive device and method for making the same to solve the above-mentioned problem.

### BRIEF SUMMARY OF THE INVENTION

One aspect of the disclosure relates to a semiconductor device. In one embodiment, the semiconductor device includes a substrate and a plurality of integrated passive devices. The substrate has a first surface and a second surface opposite to the first surface. The integrated passive devices are disposed on the first surface of the substrate and include a plurality of capacitors, wherein the capacitance values of at least two capacitors are different.

In another embodiment, the semiconductor device includes an integrated passive device and a transceiver. The integrated passive device includes a substrate having a first surface, a second surface opposite to the first surface and a plurality of capacitors disposed on the first surface of the substrate, wherein the capacitors include at least a first capacitor having a first capacitance value and a second capacitor having a second capacitance value different from the first capacitance value. The transceiver has a first terminal coupled to the first capacitor and a second terminal coupled to the second capacitor.

Another aspect of the disclosure relates to a process for fabricating a semiconductor device having one or more integrated passive devices. In one embodiment, the semiconductor process includes the steps of: (a) forming a first metal layer on a first surface of a substrate; (b) forming a second metal layer on the first metal layer; (c) thickening a part of the second metal layer so that the second metal layer has a thick portion and a thin portion; (d) forming a third metal layer on the second metal layer; and (e) selectively removing the first metal layer, the second metal layer and the third metal layer so as to form a plurality of capacitors, wherein one of the capacitors has a part of the thick portion of the second metal layer, and another of the capacitors has a part of the thin portion of the second metal layer.

### BRIEF DESCRIPTION OF THE DRAWINGS

These, as well as other features of the present invention, will become more apparent upon reference to the drawings wherein:

FIG. 1 is a cross-sectional view of a semiconductor device according to one embodiment of the present invention and having an integrated passive device;

FIG. 2 is a schematic of an exemplary radio frequency (RF) system suitable for use in conjunction with a semiconductor device having an IPD circuit;

FIG. 3A is a cross-sectional view of a semiconductor device according to another embodiment of the present invention and having an integrated passive device;

FIG. 3B is a cross-sectional view of the semiconductor device shown in FIG. 3A in combination with a transceiver;

FIG. 4 is a cross-sectional view of a semiconductor device according to another embodiment of the present invention and having an integrated passive device;

FIG. 5 is a cross-sectional view of a semiconductor device according to another embodiment of the present invention and having an integrated passive device;

FIGS. 6-17 illustrate an exemplary sequence of steps for manufacturing the semiconductor device shown in FIG. 1; and

FIGS. 18-22 illustrate an alternative exemplary sequence of steps for manufacturing the semiconductor device shown in FIG. 1.

Common reference numerals are used throughout the drawings and the detailed description to indicate the same elements. The present invention will be more apparent from the following detailed description taken in conjunction with the accompanying drawings.

### DETAILED DESCRIPTION OF THE INVENTION

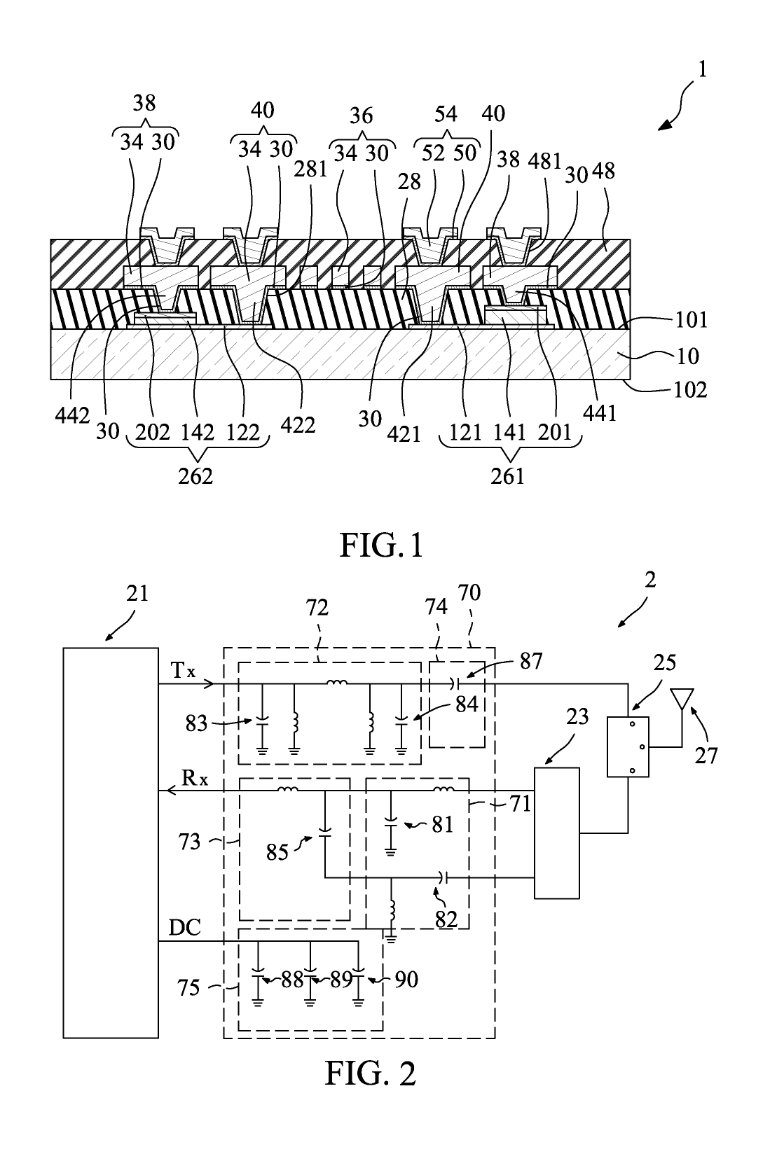

Referring now to FIG. 1, there is provided a cross-sectional view of a semiconductor device 1 according to one embodiment of the present invention and having at least one integrated passive device. The semiconductor device 1 includes a substrate 10, a plurality of integrated passive devices (e.g., a first capacitor 261, a second capacitor 262 and an inductor 36), a first protection layer 28, a first inner interconnection metal 421, a first outer interconnection metal 441, a second inner interconnection metal 422, a second outer interconnection metal 442, a plurality of connection pads 40, a redistribution layer 38, a second protection layer 48 and a plurality of under bump metallurgies (UBMs) 54.

The substrate 10 has a first surface 101 and a second surface 102 opposite to the first surface 101. In embodiment shown in FIG. 1, the material of the substrate 10 is glass to impart very low loss non-conductive properties thereto. However, it is contemplated that the material of the substrate 10 may alternatively be a semiconductor material such as silicon or germanium.

The first capacitor 261 is disposed adjacent to the first surface 101 of the substrate 10, and has a first upper electrode 201, a first intermediate insulation layer 141 and a first lower electrode 121. The first intermediate insulation layer 141 is disposed or captured between the first upper electrode 201 and the first lower electrode 121. In addition, the area of the first upper electrode 201 is substantially equal to that of the first intermediate insulation layer 141, with the area of the first lower electrode 121 being greater than that of the first intermediate insulation layer 141. As a result, when viewed from the perspective shown in FIG. 1, the peripheral side surface of the first upper electrode 201 is substantially flush or coplanar to the peripheral side surface of the first intermediate insulation layer 141, while at least a portion of the peripheral side surface of the first lower electrode 121 is disposed outwardly beyond the peripheral side surface of the first intermediate insulation layer 141.

Like the first capacitor 261, the second capacitor 262 is disposed adjacent to the first surface 101 of the substrate 10, and has a second upper electrode 202, a second intermediate insulation layer 142 and a second lower electrode 122. The second intermediate insulation layer 142 is disposed or captured between the second upper electrode 202 and the second lower electrode 122. In addition, the area of the second upper electrode 202 is substantially equal to that of the second intermediate insulation layer 142, with the area of the second lower electrode 122 being greater than that of the second intermediate insulation layer 142. As a result, as also viewed from the perspective shown in FIG. 1, the peripheral side surface of the second upper electrode 202 is substantially flush or coplanar to the peripheral side surface of the second intermediate insulation layer 142, while at least a portion of the peripheral side surface of the second lower electrode 122 is disposed outwardly beyond the peripheral side surface of the second intermediate insulation layer 142.

In the embodiment shown in FIG. 1, the material of the first upper electrode 201, the first lower electrode 121, the second upper electrode 202 and the second lower electrode 122 is preferably AlCu. The material of the first intermediate insulation layer 141 and the second intermediate insulation layer 142 is preferably Ta₂O₅, or Ta with Ta₂O₅. However, the material of the first intermediate insulation layer 141 may be different from that of the second intermediate insulation layer 142. It is understood that when the material of the substrate 10 is a semiconductor material, a barrier layer (not shown) must be disposed between the first lower electrode 121 and the substrate 10, and between the second lower electrode 122 and the substrate 10.

In the semiconductor device 1, the thicknesses of the intermediate insulation layers 141, 142 of the capacitors 261, 262 are different. More particularly, the thickness of the first intermediate insulation layer 141 of the first capacitor 261 is greater than that of the second intermediate insulation layer 142 of the second capacitor 262. In this regard, the capacitance value (C) of each of the first and second capacitors 261, 262 is determined by the following formula:

C=εA÷d

wherein ε is the dielectric constant of the dielectric layer between two electrodes, A is the area of the electrode and d is the thickness of the dielectric layer between two electrodes. When the ε and A are constant, C is in inverse proportion to d. In the semiconductor device 1, the capacitance value of the second capacitor 262 is greater than that of the first capacitor 261, since the thickness of the first intermediate insulation layer 141 of the first capacitor 261 is greater than that of the second intermediate insulation layer 142 of the second capacitor 262. Accordingly, the capacitance values of the capacitors 261, 262 are different from each other.

In the semiconductor device 1, the first protection layer 28 covers the first capacitor 261, the second capacitor 262 and the first surface 101 of the substrate 10. A plurality of openings 281 is formed in the first protection layer 28 to expose portions of the first lower electrode 121, the second lower electrode 122, the first upper electrode 201 and the second upper electrode 202. The first protection layer 28 is preferably a polymer such as benzocyclobutene (BCB), polyimide (PI), polypropylene (PP) or an epoxy. However, it is contemplated that the material of the first protection layer 28 may alternatively be silicon oxide or silicon nitride.

The first inner interconnection metal 421 is disposed in a corresponding one of the openings 281 of the first protection layer 28 and is electrically connected to the first lower electrode 121. In the semiconductor device 1, a first seed layer 30 is disposed between the first inner interconnection metal 421 and the first protection layer 28. The first outer interconnection metal 441 is disposed in a corresponding one of the openings 281 of the first protection layer 28 and is electrically connected to the first upper electrode 201. Another first seed layer 30 is disposed between the first outer interconnection metal 441 and the first protection layer 28. Similarly, the second inner interconnection metal 422 is disposed in a corresponding one of the openings 281 of the first protection layer 28 and is electrically connected to the second lower electrode 122. Another first seed layer 30 is disposed between the second inner interconnection metal 422 and the first protection layer 28. The second outer interconnection metal 442 is also disposed in a corresponding one of the opening 281 of the first protection layer 28 and is electrically connected to the second upper electrode 202. Another first seed layer 30 is disposed between the second outer interconnection metal 442 and the first protection layer 28. The material of each first seed layer 30 is preferably TiCu, with the material of each of the interconnection metals 441, 421, 422, 442 preferably being Cu. However, it is contemplated that each first seed layer 30 may be omitted from within each of the openings 281.

In the semiconductor device 1, the connection pads 40 are formed on respective ones of the first and second inner interconnection metals 421, 422. Therefore, the connection pads 40 are electrically connected to the first and second inner interconnection metals 421, 422, and hence respective ones of the first and second lower electrodes 121, 122. Similarly, the redistribution layer 38 is formed on each of the first and second outer interconnection metals 441, 442. As such, the redistribution layer 38 is electrically connected to both the first and second outer interconnection metals 441, 442, and hence each of the first and second upper electrodes 201, 202. Each of the connection pads 40 and the redistribution layer 38 comprises the combination of a first seed layer 30 and a metal layer 34. As indicated above, the material of the first seed layer 30 included in each of the connection pads 40 and the redistribution layer 38 is preferably TiCu, with the material of each metal layer 34 preferably being Cu. However, it is contemplated that the first seed layer 30 may be omitted from each of the connection pads 40 and the redistribution layer 38. In addition, it is contemplated that the first seed layer 30 of each connection pad 40 may be formed simultaneously with the first seed layer 30 included with the corresponding one of the first and second inner interconnection metals 421, 422. Similarly, it is contemplated that the first seed layer 30 of the redistribution layer 38 may be formed simultaneously with the first seed layers 30 included with the corresponding first and second outer interconnection metals 441, 442.

Like the first and second capacitors 261, 262, the inductor 36 is disposed adjacent to the first protection layer 28. In the semiconductor device 1, the inductor 36 comprises another first seed layer 30 in combination with another metal layer 34. The inductor 36 is electrically connected to the connection pads 40, and hence the first and second inner interconnection metals 421, 422 as well as the first and second lower electrodes 121, 122. As indicated above, the material of the first seed layer 30 included in the inductor 36 is preferably TiCu, with the material of the metal layer 34 thereof preferably being Cu as well. However, it is contemplated that the first seed layer 30 may also be omitted from the inductor 36 of the semiconductor device 1.

The second protection layer 48 of the semiconductor device 1 covers the inductor 36, the connection pads 40, the redistribution layer 38 and the first protection layer 28, and has a plurality of openings 481 formed therein to expose portions of the connection pads 40 and the redistribution layer 38. The second protection layer 48 is preferably a polymer such as benzocyclobutene (BCB), polyimide (PI), polypropylene (PP) or an epoxy. However, it is contemplated that the material of the second protection layer 48 may alternatively be silicon oxide or silicon nitride. Further, the material of the second protection layer 48 may be the same as or different from that of the first protection layer 28.

Each of the under bump metallurgies (UBMs) 54 is disposed in a respective one of the openings 481 of the second protection layer 48 to contact either a corresponding one of the connection pads 40 or the redistribution layer 38. As such, the under bump metallurgies 54 are each electrically connected to a corresponding one of the first and second capacitors 261, 262. In the semiconductor device 1, each under bump metallurgy 54 comprises a metal layer 52 and a corresponding second seed layer 50. The metal layer 52 is a single layer or multi-layered structure. The material of the second seed layer 50 is preferably TiCu, with the material of the metal layer 52 preferably being Ni/Pd/Au, Ni/Au or Ni/Pd. However, it is contemplated that the second seed layer 50 may be omitted from each under bump metallurgy 54 in the semiconductor device 1.

As shown in FIG. 1, the first capacitor 261, the inductor 36 and the second capacitor 262 are electrically connected in series, with the capacitance values of the first capacitor 261 and the second capacitor 262 being different from each other. In other embodiments, it is contemplated that the first capacitor 261 and the inductor 36 may be electrically connected in series, with the second capacitor 262 being electrically isolated from the inductor 36 by disconnecting the second lower electrode 122 thereof from the corresponding connection pad 40, and the capacitance values of the first capacitor 261 and the second capacitor 262 being different from each other as well. Along these lines, the interconnection of the first capacitor 261, the inductor 36 and the second capacitor 262 is dependent on a prescribed design requirement.

Referring now to FIG. 2, there is shown an exemplary radio frequency (RF) system according to the present invention which may comprise a suitable platform for the integration of a semiconductor device (such as the semiconductor device 1) having at least one integrated passive device. The RF system 2 includes a transceiver 21, an integrated passive device (IPD) circuit 70, a low noise amplifier (LNA) 23, a diplexer 25 and an antenna 27. The transceiver 21, the IPD circuit 70, the LNA amplifier 23, and the diplexer 25 are coupled to the antenna 27 for the transmission and reception of RF signals. The transceiver 21 includes at least a first terminal (Tx), a second terminal (Rx) and a third terminal (DC) to route respective ones of a transmit RF signal, a receive RF signal and a reference signal to the IPD circuit 70. The IPD circuit 70 filters the RF signal transmitted to/received from the transceiver 21, and regulates the reference voltage (DC), such as driving voltage and ground voltage, for the transceiver 21. That is, the transceiver 21 is coupled to the IPD circuit 70 to eliminate RF signal interference.

As shown in FIG. 2, the IPD circuit 70 provides the circuit function including a balun circuit 71, a band pass filter (BPF) 72, a RF matching circuit 73, a DC block capacitor 74, and decoupling capacitors 75. The first terminal Tx of the transceiver 21 is coupled to the band pass filter 72 and the DC block capacitor 74, with the diplexer 25 being electrically connected to the DC block capacitor 74. The band pass filter (BPF) 72 includes a third capacitor 83 and a fourth capacitor 84, wherein the capacitance values of the third capacitor 83 and the fourth capacitor 84 are each in the range of from about 0.1 to 10 pF. The DC block capacitor 74 includes a seventh capacitor 87, wherein the capacitance value of the seventh capacitor 87 is in the range of from about 0.1 to 10 pF. The second terminal Rx of the transceiver 21 is coupled to the balun circuit 71 and the RF matching circuit 73, with the low noise amplifier 23 being electrically connected to the balun circuit 71. The balun circuit 71 includes a first capacitor 81 and a second capacitor 82, wherein the capacitance values of the first capacitor 81 and the second capacitor 82 are each in the range of from about 0.1 to 10 pF. The RF matching circuit 73 includes a fifth capacitor 85, wherein the capacitance value of the fifth capacitor 85 is in the range of from about 0.1 to 10 pF. The third terminal DC of the transceiver 21 is coupled to the decoupling capacitors 75. The decoupling capacitors 75 include an eighth capacitor 88, a ninth capacitor 89 and a tenth capacitor 90, wherein the capacitance values of the eighth capacitor 88, the ninth capacitor 89 and the tenth capacitor 90 are each in the range of from about 10 to 1000 pF. The difference of the capacitance value between the above two circuits, for example, the balun circuit 71 and the decoupling capacitor 75, the band pass filter (BPF) 72 and the decoupling capacitors 75, the RF matching circuit 73 and the decoupling capacitors 75, or the DC block capacitor 74 and the decoupling capacitor 75, is about 100 times.

As further shown in FIG. 2, the balun circuit 71 is coupled to the low noise amplifier 23, wherein the first capacitor 81 of the balun circuit 71 is coupled to low noise amplifier 23 through the inductor 36, and the second capacitor 82 of the balun circuit 71 is coupled to the low noise amplifier 23. The seventh capacitor 87 of the DC block capacitor 74 and a terminal of the low noise amplifier 23 are coupled to the diplexer 25, which is coupled to the antenna 27.

By way of example, a semiconductor device (such as the semiconductor device 1) fabricated to include the balun circuit 71 and the decoupling capacitor 75 would further include two integrated passive devices with different capacitance values, one of which is in the range of from about 0.1 to 10 pF (the first capacitor 81 and the second capacitor 82 of the balun circuit 71), with the other being in the range of from about 10 to 1000 pF (the eighth capacitor 88, the ninth capacitor 89 and the tenth capacitor 90 of the decoupling capacitors 75). In the context of the semiconductor device 1 shown in FIG. 1, by choosing a suitable thicknesses and materials for the first intermediate insulation layer 141 of the first capacitor 261 and the second intermediate insulation layer 142 of the second capacitor 262, the IPD circuit 70 having different capacitance values can be easily accomplished in the semiconductor device 1.

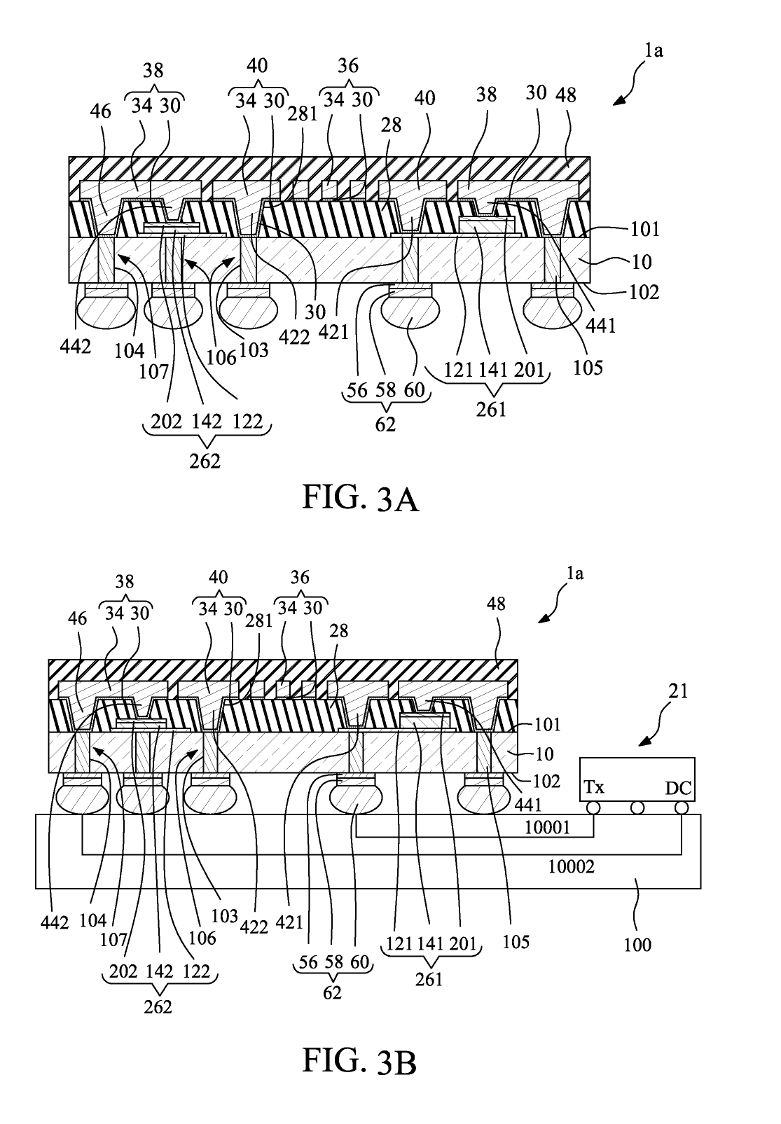

Referring now to FIG. 3A, there is shown a cross-sectional view of a semiconductor device 1a according to another embodiment of the present invention and having at least one integrated passive device. The semiconductor device 1a shown in FIG. 3A is substantially similar to the semiconductor device 1 shown in FIG. 1, with the same elements being designated with same reference numerals. In this regard, the differences between the semiconductor devices 1, 1a are highlighted below.

In the semiconductor device 1a, the first capacitor 261 is electrically connected to the inductor 36 in series, and the second capacitor 262 is electrically disconnected from the first capacitor 261 and the inductor 36, with the capacitance value of the first capacitor 261 and the second capacitor 262 also being different from each other. The substrate 10 further has a plurality of first (inner) through holes 103, a plurality of second (outer) through holes 104, a plurality of conductive metals 105, a plurality of first conductive vias 106 and a plurality of second conductive vias 107. The through holes 103, 104 each extend between the first and second surfaces 101, 102 of the substrate 10. In the semiconductor device 1a, the conductive metals 105 are Cu, and fill each of the first and second through holes 103, 104. In this regard, the, each first conductive vias 106 is collectively defined by the combination of a first through hole 103 and a corresponding metal 105, with each second conductive via 107 being collectively defined by the combination of a second through hole 104 and a corresponding metal 105. The first conductive vias 106 and the second conductive vias 107 are exposed in both the first surface 101 and the second surface 102 of the substrate 10. In addition, one of the first conductive vias 106 contacts the first lower electrode 121 of the first capacitor 261, with another one of the first conductive vias 106 contacting the second lower electrode 122 of the second capacitor 262. Therefore, the conductive vias 106, 107 penetrate through the substrate 10 and are electrically connected to the capacitors 261, 262.

As further shown in FIG. 3A, certain ones of the openings 281 of the first protection layer 28 expose corresponding ones of the second conductive vias 107. A plurality of interconnection metals 46 are disposed in respective ones of these particular openings 281 so as to electrically connect to respective ones of the second conductive vias 107. These interconnection metals 46 are also each integrally connected to the redistribution layer 38. In addition, the semiconductor device 1a further includes a plurality of conductive elements 62 disposed on the second surface 102 of the substrate 10 and electrically connected to respective ones of the first conductive vias 106 and the second conductive vias 107. In the semiconductor device 1a, each of the conductive elements 62 includes the combination of a seed layer 56, an under bump metallurgy (UBM) 58 and a bump 60. As such, the semiconductor device 1a does not include the under bump metallurgies (UBMs) 54 of FIG. 1.

Referring now to FIG. 3B, there is shown an exemplary system having the semiconductor device 1a integrated therein. The system includes a printed circuit board 100, the transceiver 21 and the semiconductor device 1a. As shown in FIG. 3B, the semiconductor device 1a is electrically connected to the transceiver 21 through the layout of the printed circuit board 100. In the transmit section of the transceiver 21, the first upper electrode 201 of the first capacitor 261 is electrically connected to the ground voltage, and the first lower electrode 121 connected with the first inner interconnection metal 421 is electrically connected to the first terminal Tx of the transceiver 21 through a corresponding bump 60 and a first route 1001 of the printed circuit board 100. The second upper electrode 202 of the second capacitor 262 is electrically connected to the third terminal DC of the transceiver 21 through the second conductive via 107, a corresponding bump 60 and a second route 10002 of the printed circuit board 100. The second lower electrode 122 is electrically connected to the ground voltage through a corresponding bump 60. Alternatively, the inductor 36 may be electrically connected to the first capacitor 261 and the second terminal Rx of the transceiver 21 in series, and the second capacitor 262 may be electrically connected to the third terminal DC of the transceiver 21. The use of glass as the material of the substrate 10 is important for RF signal transmission because of its excellent dielectric property.

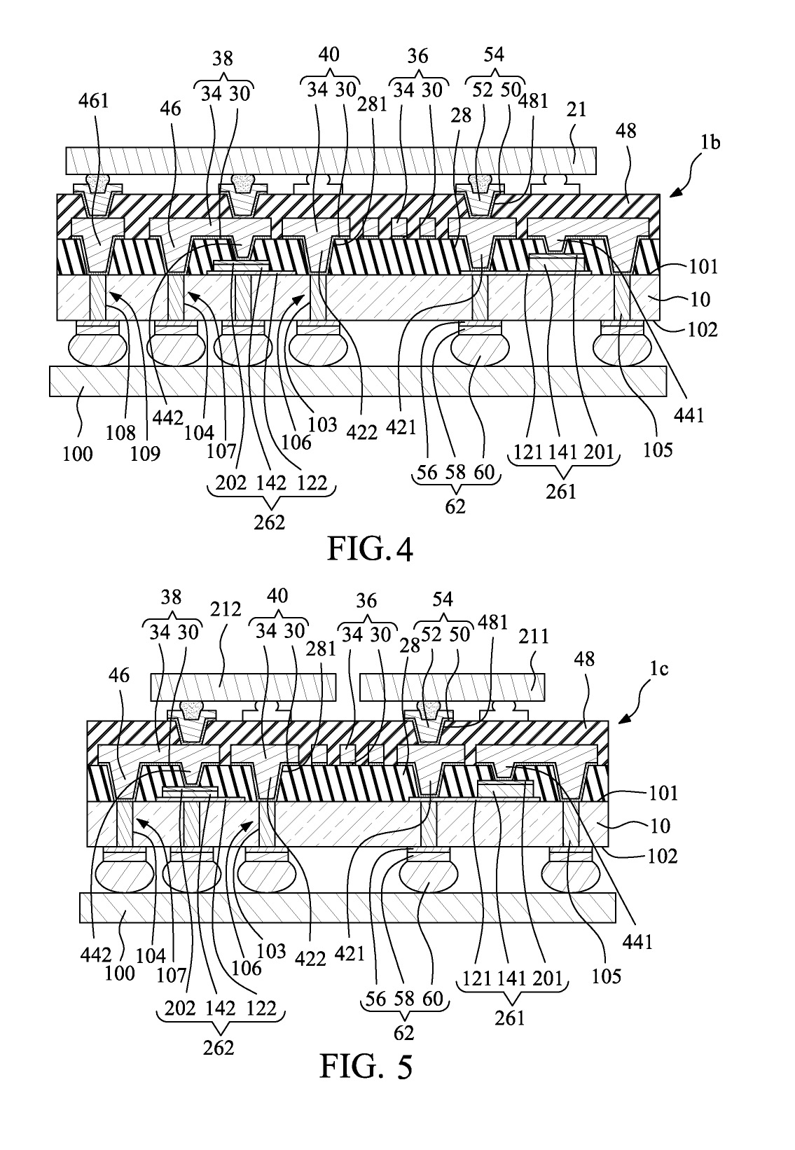

Referring now to FIG. 4, there is shown another exemplary system having a semiconductor device 1b integrated therein which is similar to, but a slight variation of, the semiconductor device 1a described above. The semiconductor device 1b shown in FIG. 4 is substantially similar to the semiconductor device 1a shown in FIG. 3A, with the same elements being designated with same reference numerals. In this regard, the differences between the semiconductor devices 1a, 1b are highlighted below.

The system shown in FIG. 4 includes the printed circuit board 100, the transceiver 21 and the semiconductor device 1b. The transceiver 21 is attached to the second protection layer 48, and is electrically connected to under bump metallurgies (UBMs) 54 (like those described in relation to the semiconductor device 1) which are included in the semiconductor device 1b and extend through the protection layer 48 into electrical communication with the first lower electrode 121 of the first capacitor 261 and the first upper electrode 202 of the second capacitor 262. The printed circuit board 100 is attached to the second surface 102 of the substrate 10, and the first conductive vias 106 and the second conductive vias 107 are electrically connected to the printed circuit board 100 through the conductive elements 62. In addition, the substrate 10 further has at least one third through hole 108 formed therein and extending between the first and second surfaces 101, 102 thereof. Like the first and second through holes 103, 104, the third through hole 108 is filled with a conductive metal 105. The combination of the third through hole 108 and the corresponding conductive metal 105 collectively define a third conductive via 109. The third conductive via 109 is exposed from the first surface 101 and the second surface 102 of the substrate 10. One of the openings 281 of the first protection layer 28 further exposes the third conductive via 109. An interconnection metal 461 is disposed in this particular opening 281 so as to be electrically connected to the third conductive via 109. Therefore, the transceiver 21 can be electrically connected to the printed circuit board 100 through the interconnection metal 461, the third conductive via 109 and a corresponding UBM 54 electrically connected to the interconnection metal 461, with such electrical path not including the integrated passive devices (e.g., the first capacitor 261, the second capacitor 262 and the inductor 36).

Referring now to FIG. 5, there is shown another exemplary system having a semiconductor device 1c integrated therein which is similar to, but a slight variation of, the semiconductor device 1b described above. The semiconductor device 1c shown in FIG. 5 is substantially similar to the semiconductor device 1b shown in FIG. 4, with the same elements being designated with same reference numerals. In this regard, the sole distinction between the semiconductor devices 1b, 1c is the omission of the third conductive via 109, the interconnection metal 461 (and corresponding UBM 54) as described above.

The system shown in FIG. 5 includes a printed circuit board 100, a first transceiver 211, a second transceiver 212 and the semiconductor device 1c. The first transceiver 211 is electrically connected to the first capacitor 261, and the second transceiver 212 is electrically connected to the second capacitor 262. Thus, the first transceiver 211 and the second transceiver 212 are electrically connected to different capacitors with different capacitance values, which results in more flexibility of layout design.

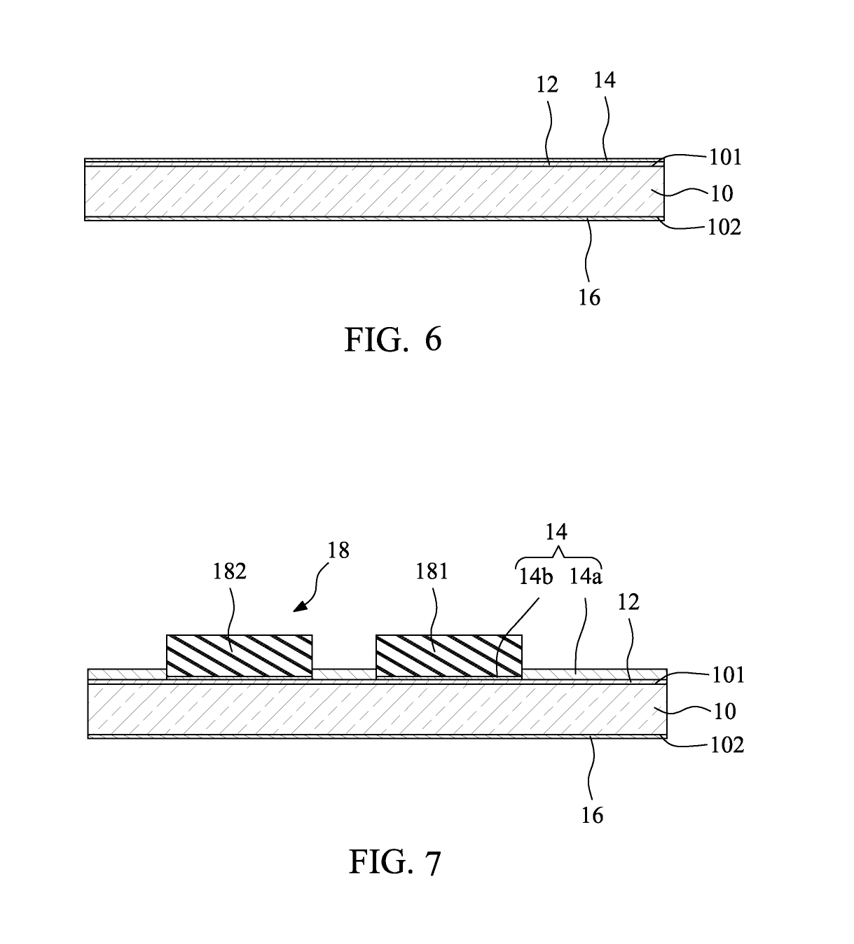

Referring now to FIGS. 6-17, there is shown an exemplary sequence of steps for manufacturing the semiconductor device 1. In the initial step of the fabrication process shown in FIG. 6, the above-described substrate 10 is provided. As indicated above, the substrate 10 defines the first surface 101 and the second surface 102 opposite to the first surface 101. The material of the substrate 10 is preferably glass, though it may alternatively be a semiconductor material such as silicon or germanium. Thereafter, a first metal layer 12 is formed on the first surface 101 of the substrate 10 by sputtering. The material of the first metal layer 12 is preferably AlCu. Next, a second metal layer 14 is formed on the first metal layer 12 by sputtering, with a bottom metal layer 16 then being formed on the second surface 102 of the substrate 10 by sputtering. The material of the second metal layer 14 is preferably Ta, which is the same as the material of the bottom metal layer 16.

In the next step of the fabrication process shown in FIG. 7, a first photoresist layer 18 is formed on the second metal layer 14. The first photoresist layer 18 has a prescribed pattern to expose a portion of the second metal layer 14. More particularly, the pattern of the first photoresist layer 18 includes a first solid portion 181 and a second solid portion 182. The exposed portion of the second metal layer 14 (not covered by the first solid portion 181 and the second solid portion 182) is defined as a first part 14a, and the unexposed portion of the second metal layer 14 that is covered by the first solid portion 181 and the second solid portion 182 is defined as a second part 14b. The exposed part (the first part 14a) of the second metal layer 14 is then treated, e.g., oxidized and thickened. The oxidization process is preferably an anodization process, with part of the Ta of the first part 14a becoming Ta₂O₅. It is noted that unexposed part (the second part 14b) of the second metal layer 14 is not treated.

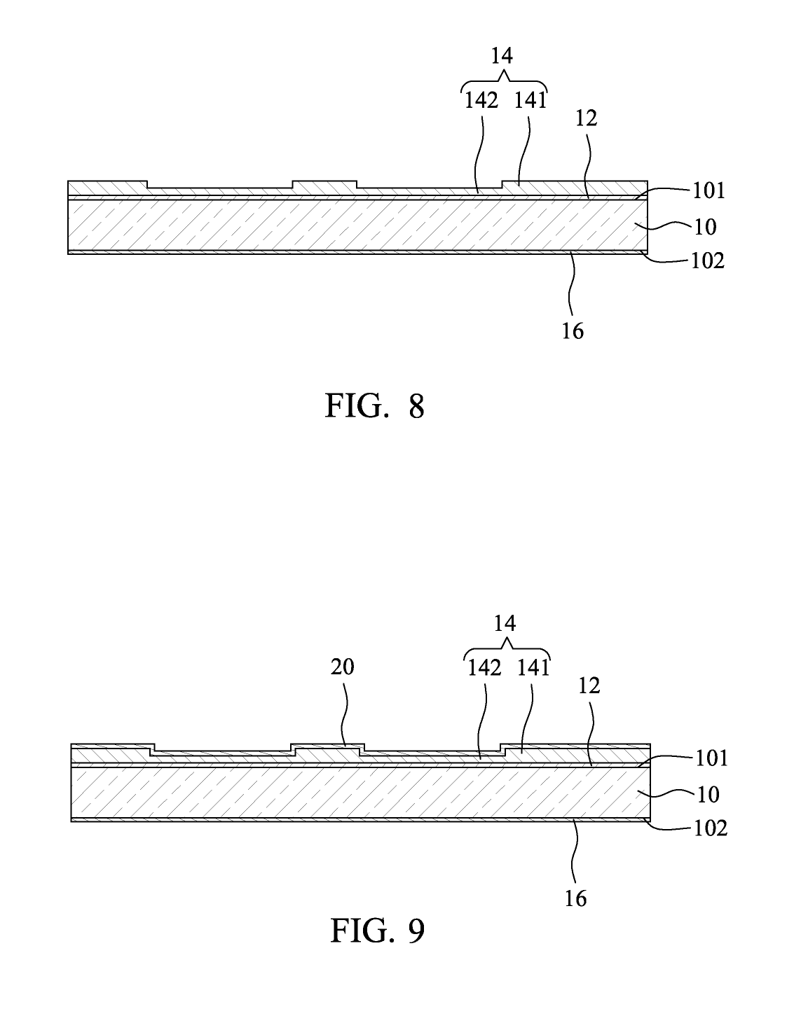

In the next step of the fabrication process shown in FIG. 8, the first photoresist layer 18 is removed. The entire second metal layer 14 is then treated, e.g., oxidized again and thickened so that the second metal layer 14 becomes an insulation layer (i.e., Ta₂O₅) and defines a thick portion 141 and a thin portion 142. Specifically, another part of the Ta of the first part 14a of the second metal layer 14 becomes Ta₂O₅, so as to form the thick portion 141. Part of the Ta of the second part 14b of the second metal layer 14 becomes Ta₂O₅, so as to form the thin portion 142. Since the thick portion 141 is formed by a two-time oxidization processes, and the thin portion 142 is formed by a one-time oxidization process, the thick portion 141 is thicker than the thin portion 142. The material of the thick portion 141 and the thin portion 142 is preferably Ta₂O₅, though it may alternatively be Ta with Ta₂O₅.

In the next step of the fabrication process shown in FIG. 9, a third metal layer 20 is formed on the second metal layer 14 by sputtering. The material of the third metal layer 20 is preferably AlCu.

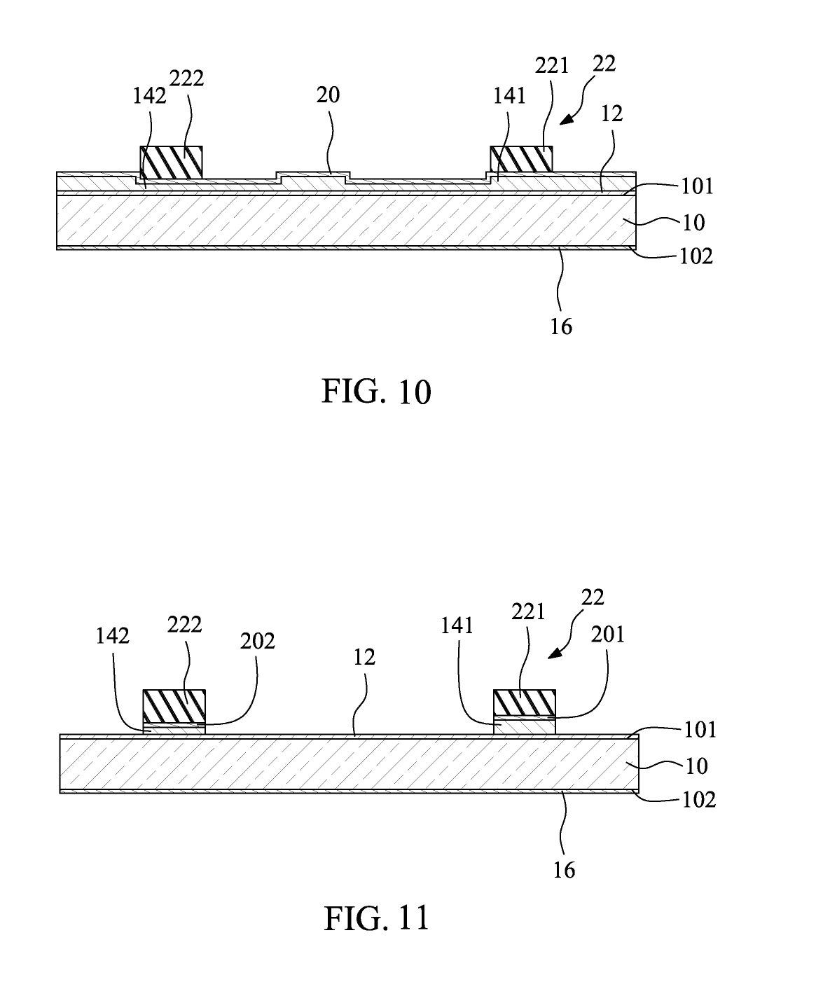

In the next step of the fabrication process shown in FIG. 10, a second photoresist layer 22 is formed on the third metal layer 20. The second photoresist layer 22 has a first solid portion 221 and a second solid portion 222. The first solid portion 221 corresponds to the thick portion 141 of the second metal layer 14, and the second solid portion 222 corresponds to the thin portion 142 of the second metal layer 14.

In the next step of the fabrication process shown in FIG. 11, the third metal layer 20 and the second metal layer 14 are selectively removed according to the second photoresist layer 22. The portions of the third metal layer 20 and the second metal layer 14 that are not covered by the first solid portion 221 and the second solid portion 222 are preferably removed by dry etching.

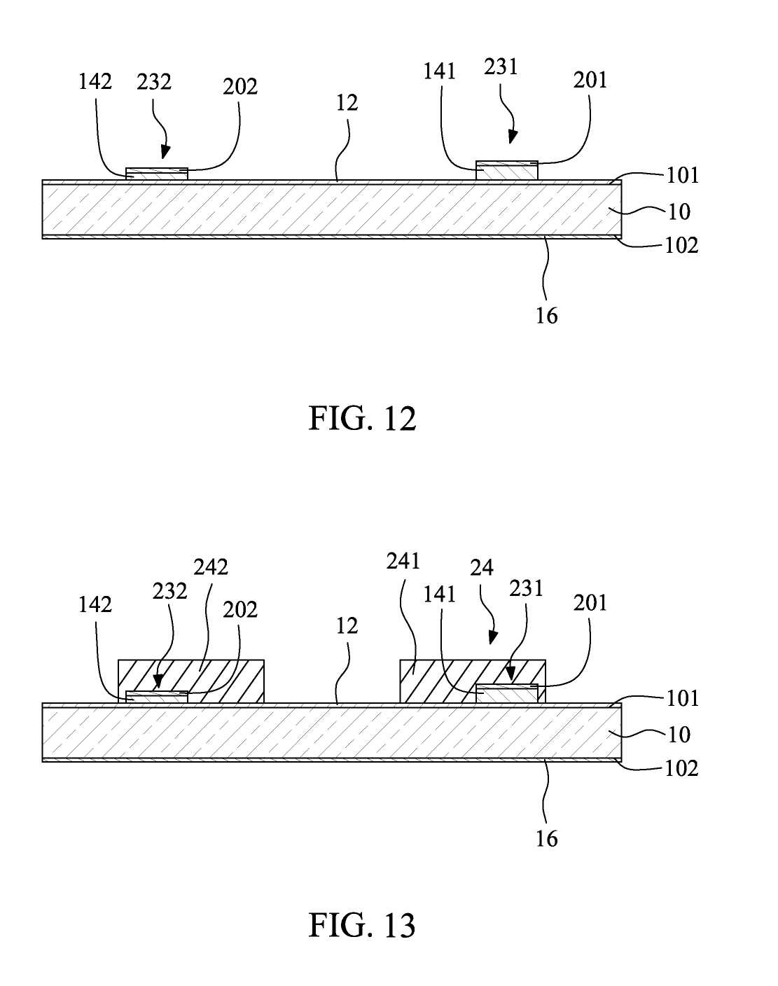

In the next step of the fabrication process shown in FIG. 12, the second photoresist layer 22 is removed so as to form at least one thick remaining unit 231 and at least one thin remaining unit 232. The thick remaining unit 231 has a part of the thick portion 141 of the second metal layer 14, and the thin remaining unit 232 has a part of the thin portion 142 of the second metal layer 14.

In the next step of the fabrication process shown in FIG. 13, a third photoresist layer 24 is formed on the first metal layer 12, the thick remaining unit 231 and the thin remaining unit 232. The third photoresist layer 24 has a first solid portion 241 and a second solid portion 242. The first solid portion 241 covers the thick remaining unit 231 and a portion of the first metal layer 12, with the second solid portion 242 covering the thin remaining unit 232 and another portion of the first metal layer 12.

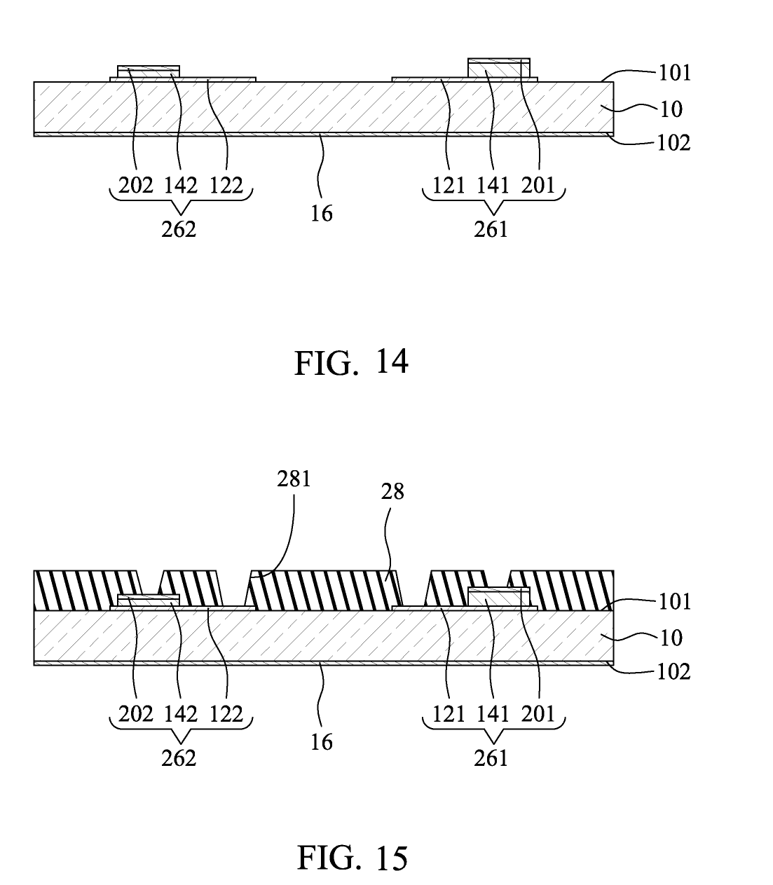

In the next step of the fabrication process shown in FIG. 14, the first metal layer 12 is selectively removed according to the third photoresist layer 24. The portion of the first metal layer 12 that is not covered by the first solid portion 241 and the second solid portion 242 is preferably removed by dry etching. The third photoresist layer 24 is then removed so as to simultaneously form the first capacitor 261 and the second capacitor 262. As previously explained, the first capacitor 261 includes the first upper electrode 201, the first intermediate insulation layer 141 and the first lower electrode 121, the first intermediate insulation layer 141 being between the first upper electrode 201 and the first lower electrode 121, with the area of the first upper electrode 201 being substantially equal to that of the first intermediate insulation layer 141 and the area of the first lower electrode 121 being greater than that of the first intermediate insulation layer 141. As indicated above, the area and position of the first upper electrode 201 and the first intermediate insulation layer 141 are determined by the first solid portion 221 of the second photoresist layer 22. As also indicated above, the area and position of the first lower electrode 121 are determined by the first solid portion 241 of the third photoresist layer 24.

As also previously explained, the second capacitor 262 includes the second upper electrode 202, the second intermediate insulation layer 142 and the second lower electrode 122, the second intermediate insulation layer 142 being captured between the second upper electrode 202 and the second lower electrode 122, with area of the second upper electrode 202 being substantially equal to that of the second intermediate insulation layer 142 and the area of the second lower electrode 122 being greater than that of the second intermediate insulation layer 142. As indicated above, the area and position of the second upper electrode 202 and the second intermediate insulation layer 142 are determined by the second solid portion 222 of the second photoresist layer 22. As also indicated above, the area and position of the second lower electrode 122 are determined by the second solid portion 242 of the third photoresist layer 24. The thickness of the first intermediate insulation layer 141 of the first capacitor 261 is greater than that of the second intermediate insulation layer 142 of the second capacitor 262.

In the next step of the fabrication process shown in FIG. 15, the first protection layer 28 is formed on the capacitors 261, 262 and the first surface 101 of the substrate 10. The first protection layer 28 has the plurality of openings 281 formed therein to expose portions of the first lower electrode 121, the second lower electrode 122, the first upper electrode 201 and the second upper electrode 202.

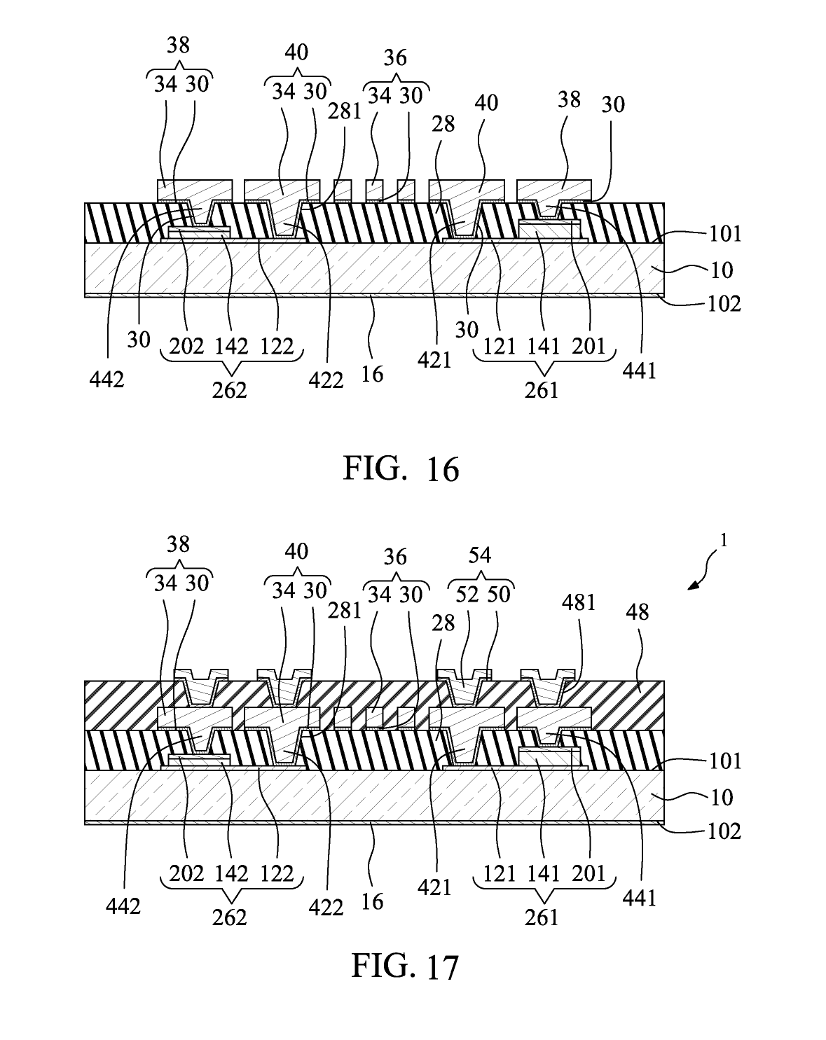

In the next step of the fabrication process shown in FIG. 16, the first inner interconnection metal 421, the second inner interconnection metal 422, the first outer interconnection metal 441 and the second outer interconnection metal 442 are formed in respective ones of the openings 281 of the first protection layer 28 and electrically connected to the first lower electrode 121, the second lower electrode 122, the first upper electrode 201 and the second upper electrode 202, respectively. The above-described first seed layers 30 are preferably disposed between the first protection layer 28 and respective ones of the first inner interconnection metal 421, the second inner interconnection metal 422, the first outer interconnection metal 441 and the second outer interconnection metal 442. However, as previously explained, each such first seed layer 30 may be omitted. In addition, the connection pads 40 are formed on the first protection layer 28 and respective ones of the first and second inner interconnection metals 421, 422, with the redistribution layer 38 being formed on the first protection layer 28 and each of the first and second outer interconnection metals 441, 442. The inductor 36 is also formed on the first protection layer 28 and electrically connected to each of the connection pads 40. As indicated above, the inductor 36, the connection pads 40 and the redistribution layer 38 each comprise a first seed layer 30 and a metal layer 34, though it is contemplated that each such first seed layer 30 may be omitted therefrom.

In the next step of the fabrication process shown in FIG. 17, a second protection layer 48 is formed on the inductor 36, the connection pads 40, the redistribution layer 38 and the first protection layer 28. The second protection layer 48 has a plurality of openings 481 to expose portions of the connection pads 40 and the redistribution layer 38. The under bump metallurgies (UBMs) 54 are then formed in the openings 481 of the second protection layer 48 to contact respective ones the connection pads 40 and the redistribution layer 38. As indicated above, each under bump metallurgy 54 comprises a metal layer 52 and a corresponding second seed layer 50. However, it is contemplated that the second seed layer 50 may be omitted from each under bump metallurgy 54. The bottom metal layer 16 is then removed, and a singulation process is performed to form the semiconductor device 1 as shown in FIG. 1.

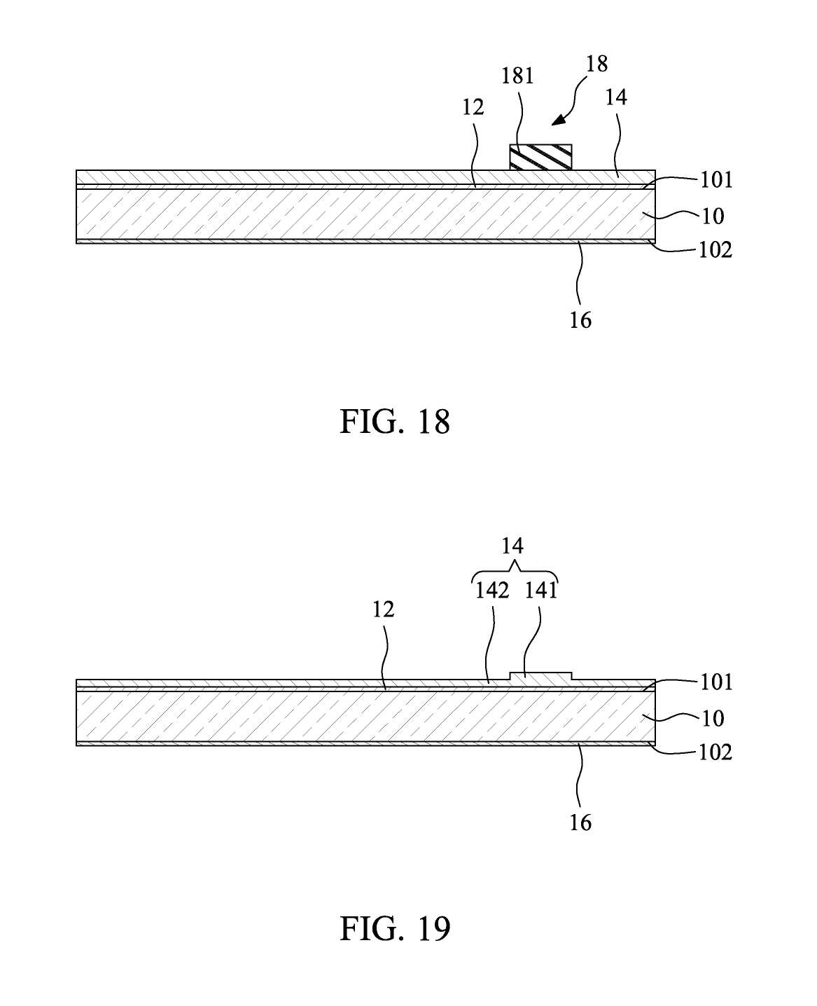

Referring now to FIGS. 18-22, there is shown an alternative exemplary sequence of steps for manufacturing the semiconductor device 1 of the present invention. The initial step of this particular, alternative fabrication process is the same as described above in relation to FIG. 6.

In the next step of the fabrication process shown in FIG. 18, all of the second metal layer 14 is treated, e.g., oxidized again and thickened so that the whole second metal layer 14 becomes an insulation layer (i.e., Ta₂O₅). A first photoresist layer 18 is then formed on the second metal layer 14. The first photoresist layer 18 has a prescribed pattern to expose a portion of the second metal layer 14. In this particular fabrication process, the pattern of the first photoresist layer 18 includes a first solid portion 181.

In the next step of the fabrication process shown in FIG. 19, the exposed portion of the second metal layer 14 is thinned. More particularly, the exposed portion of the second metal layer 14 that is not covered by the first solid portion 181 is preferably etched. The first photoresist layer 18 is then removed so that the second metal layer 14 has a thick portion 141 and a thin portion 142.

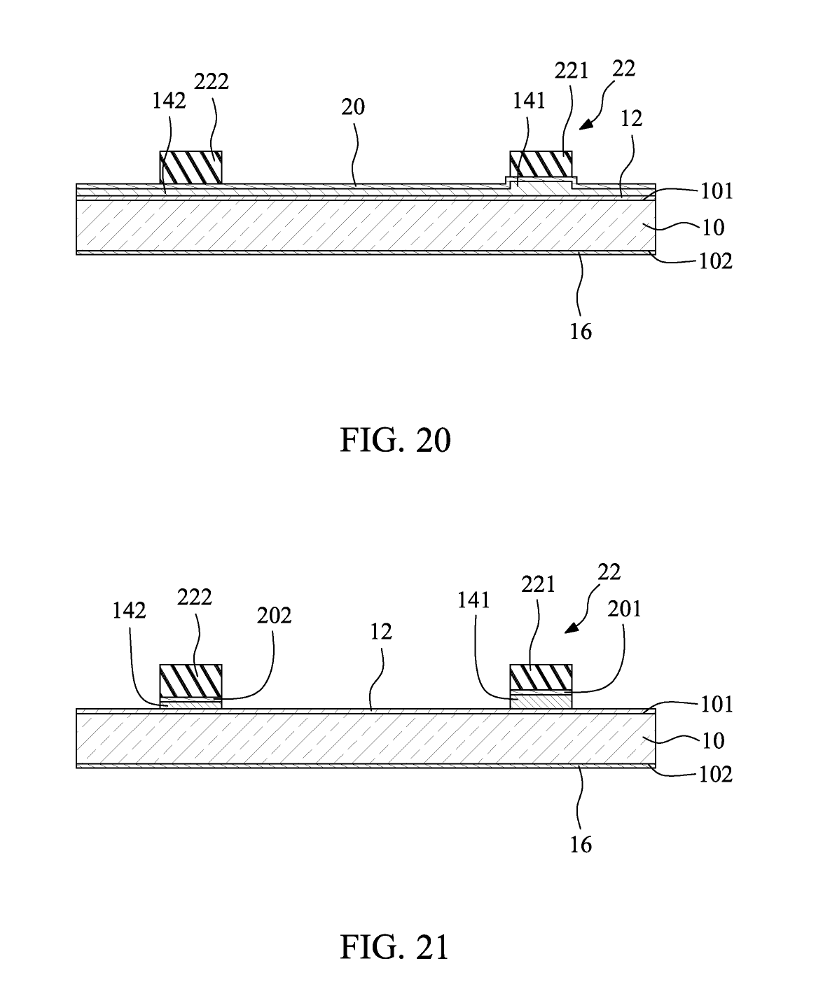

In the next step of the fabrication process shown in FIG. 20, a third metal layer 20 is formed on the second metal layer 14 by sputtering. A second photoresist layer 22 is then formed on the third metal layer 20. The second photoresist layer 22 has a first solid portion 221 and a second solid portion 222. The first solid portion 221 corresponds to the thick portion 141 of the second metal layer 14, and the second solid portion 222 corresponds to the thin portion 142 of the second metal layer 14.

In the next step of the fabrication process shown in FIG. 21, the third metal layer 20 and the second metal layer 14 are selectively removed according to the second photoresist layer 22. More particularly, the portions of the third metal layer 20 and the second metal layer 14 that are not covered by the first solid portion 221 and the second solid portion 222 are preferably removed by dry etching.

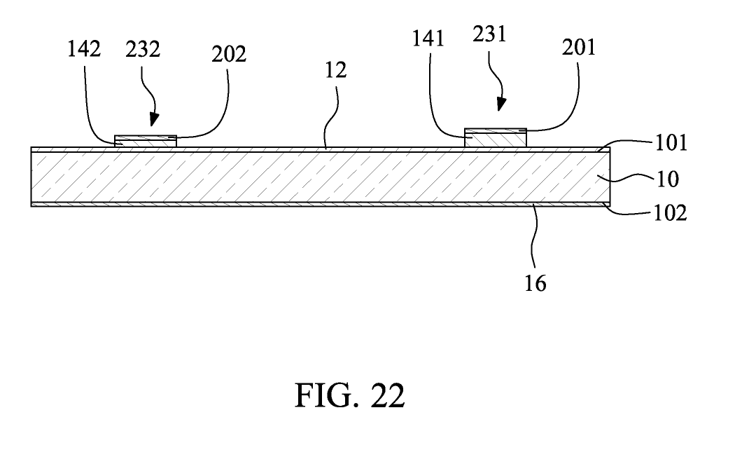

In the next step of the fabrication process shown in FIG. 22, the second photoresist layer 22 is removed so as to form at least one thick remaining unit 231 and at least one thin remaining unit 232. The thick remaining unit 231 has a part of the thick portion 141 of the second metal layer 14, and the thin remaining unit 232 has a part of the thin portion 142 of the second metal layer 14.

The subsequent steps of this alternative fabrication process are the same as those corresponding to FIGS. 13-17 as set forth above so as to form the semiconductor device 1 as shown in FIG. 1.

While the invention has been described and illustrated with reference to specific embodiments thereof, these descriptions and illustrations do not limit the invention. It should be understood by those skilled in the art that various changes may be made and equivalents may be substituted without departing from the true spirit and scope of the invention as defined by the appended claims. The illustrations may not be necessarily be drawn to scale. There may be distinctions between the artistic renditions in the present disclosure and the actual apparatus due to manufacturing processes and tolerances. There may be other embodiments of the present invention which are not specifically illustrated. The specification and the drawings are to be regarded as illustrative rather than restrictive. Modifications may be made to adapt a particular situation, material, composition of matter, method, or process to the objective, spirit and scope of the invention. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

1. A semiconductor device, comprising:
a substrate having a first surface and a second surface opposite the first surface; and
a plurality of integrated passive devices disposed on the first surface of the substrate, wherein the integrated passive devices include at least two capacitors having different capacitance values.

2. The semiconductor device of claim 1 wherein each of the capacitors comprises:
an upper electrode;
a lower electrode; and
an intermediate insulation layer captured between the upper electrode and the lower electrode;
wherein the intermediate insulation layers of the at least two capacitors are formed to be of different thicknesses.

3. The semiconductor device of claim 1 wherein one of the capacitors is band pass filter and one of the capacitors is decoupling capacitor.

4. The semiconductor device of claim 1 wherein one of the capacitors is an RF matching circuit and one of the capacitors is a decoupling capacitor.

5. The semiconductor device of claim 1 wherein the difference between the capacitance values of the at least two capacitors is about 100 times.

6. The semiconductor device of claim 1 further comprising a conductive via exposed from the first surface and the second surface of the substrate, the conductive via being electrically connected to at least one of the capacitors.

7. A semiconductor device, comprising:
an integrated passive device comprising:
a substrate; and
a first capacitor disposed on the substrate and having a first capacitance value; and
a second capacitor disposed on the substrate and having a second capacitance value different from the first capacitance value; and
a transceiver having a first terminal coupled to the first capacitor and a second terminal coupled to the second capacitor.

8. The semiconductor device of claim 7 wherein:
the first and second capacitors each comprise an upper electrode, a lower electrode formed on the substrate and an intermediate insulation layer captured between the upper electrode and the lower electrode; and
the intermediate insulation layers of the first and second capacitors are formed to be of different thicknesses.

9. The semiconductor device of claim 7 wherein the first capacitor is band pass filter and the second capacitor is decoupling capacitor.

10. The semiconductor device of claim 7 wherein the first capacitor is RF matching circuit and the second capacitor is decoupling capacitor.

11. The semiconductor device of claim 7 wherein the difference between the capacitance values of the first and second capacitors is about 100 times.

12. The semiconductor device of claim 8, further comprising:
a first conductive via disposed within the substrate and electrically connected to both the lower electrode of the first capacitor and the first terminal of the transceiver; and
a second conductive via disposed within the substrate and electrically connected to the lower electrode of the second capacitor and the second terminal of the transceiver.

13. The semiconductor device of claim 8, further comprising:
a first protection layer partially covering the substrate, the first capacitor and the second capacitor, the first protection layer having at least first and second openings formed therein, with a portion of the upper electrode of the first capacitor being exposed in the first opening and a portion of the upper electrode of the second capacitor being exposed in the second opening;
a first interconnection metal disposed in the first opening and electrically connected to both the upper electrode of the first capacitor and the first terminal of the transceiver; and
a second interconnection metal disposed in the second opening and electrically connected to both the upper electrode of the second capacitor and the second terminal of the transceiver.

14. The semiconductor device of claim 7 wherein the integrated passive device further comprises an inductor formed on the substrate and electrically connected to the first capacitor in series.

15. The semiconductor device of claim 7 wherein the integrated passive device further comprises an inductor formed on the substrate and electrically connected to a third terminal of the transceiver.

16. The semiconductor device of claim 7 wherein the substrate defines opposed first and second surfaces, and the first and second capacitors are each disposed on the first surface of the substrate.

17. (canceled)

18. (canceled)

19. (canceled)

20. (canceled)

21. A semiconductor device, comprising:
a substrate having a first surface and a second surface opposite the first surface; and
at least two capacitors disposed on the first surface of the substrate and having different capacitance values, each of the capacitors comprising:
an upper electrode;
a lower electrode; and
an intermediate insulation layer captured between the upper electrode and the lower electrode;
wherein the intermediate insulation layers of the at least two capacitors are formed to be of different thicknesses.

22. The semiconductor device of claim 21 wherein one of the capacitors is band pass filter and one of the capacitors is decoupling capacitor.

23. The semiconductor device of claim 21 wherein one of the capacitors is an RF matching circuit and one of the capacitors is a decoupling capacitor.

24. The semiconductor device of claim 21 further comprising a conductive via exposed from the first surface and the second surface of the substrate, the conductive via being electrically connected to at least one of the capacitors.
